(19) United States
(12) Patent Application Publication
(10) Pub. No.: US 2026/0182000 A1
(43) Pub. Date: Jun. 25, 2026

(54) SEMICONDUCTOR DEVICE HAVING A DIELETRIC ETCH-STOP LAYER THAT PREVENTS GATE LOSS DURING PLANARIZATION AND METHOD OF MANUFACTURING THEREOF

(71) Applicant: Taiwan Semiconductor Manufacturing Company, Ltd., Hsinchu (TW)

(72) Inventors: You-Shiang LIN, Hsinchu (TW); Yilin HSU, Hsinchu (TW); Ying-Tsungq CHEN, Hsinchu (TW)

(73) Assignee: Taiwan Semiconductor Manufacturing Company, Ltd., Hsinchu (TW)

(21) Appl. No.: 18/987,061

(22) Filed: Dec. 19, 2024

(51) Int. Cl. H10D 84/01; H10D 30/01; H10D 84/83

(52) U.S. Cl. CPC H10D 84/0153; H10D 84/832; H10D 84/834

(57) ABSTRACT

A method of forming a semiconductor device includes forming a nanostructure, forming a conductive gate structure over the nanostructure, forming a dielectric etch-stop layer over the conductive gate structure, forming an amorphous layer over the dielectric etch-stop layer, and forming a patterned mask structure over the amorphous layer. The method further includes etching the amorphous layer, the dielectric etch-stop layer, and the conductive gate structure to form an opening that divides the conductive gate structure into a first gate portion and a second gate portion that are electrically disconnected from one another; filling the opening with an insulating material; and performing a planarization operation to remove the patterned mask structure and stopping the planarization operation at the dielectric etch-stop layer. According to various embodiments, the dielectric etch-stop layer includes a thickness between 1 nm and 3 nm and none of the conductive gate structure is removed by the planarization operation.

### BACKGROUND

Semiconductor devices are employed in a variety of electronic applications, including, for example, personal computers, cell phones, digital cameras, and other electronic equipment. These devices are typically fabricated by sequentially depositing insulating (dielectric), conductive, and semiconductor material layers over a semiconductor substrate, followed by patterning these layers using lithography to form circuit components and elements. The semiconductor industry continues to enhance the integration density of various electronic components (e.g., transistors, diodes, resistors, capacitors) by progressively reducing minimum feature sizes, thereby allowing more components to be integrated within a given area. However, as minimum feature sizes decrease, additional challenges arise that must be addressed.

### BRIEF DESCRIPTION OF THE DRAWINGS

The present disclosure is best understood from the following detailed description when read with reference to the accompanying figures. It is emphasized that, per the standard practice in the industry, various features are not drawn to scale and are used for illustration purposes only. The dimensions of the various features may be arbitrarily increased or reduced for clarity of discussion.

FIG. 1A is a top view of an integrated circuit, according to various embodiments.

FIG. 1B is a vertical cross-sectional view taken along the X-X′ line shown in FIG. 1A, according to various embodiments.

FIG. 1C is a vertical cross-sectional view taken along the Y1-Y1′ line shown in FIG. 1A, according to various embodiments.

FIG. 1D is a vertical cross-sectional view taken along the Y2-Y2′ line shown in FIG. 1A, according to various embodiments.

FIG. 1E is a vertical cross-sectional view taken along the E-E′ line shown in FIG. 1A, according to various embodiments.

FIG. 1F is a top view of a structure in which an opening has been formed in the integrated circuit 10 of FIGS. 1A to 1E, according to various embodiments.

FIG. 1G is a vertical cross-sectional view taken along the X-X′ line shown in FIG. 1F, according to various embodiments.

FIG. 1H is a vertical cross-sectional view taken along the Y1-Y1′ line shown in FIG. 1F, according to various embodiments.

FIG. 1I is a vertical cross-sectional view taken along the Y2-Y2′ line shown in FIG. 1F, according to various embodiments.

FIG. 2 illustrates a top-down view of an integrated circuit, according to various embodiments.

FIG. 3A is a vertical cross-sectional view of a further structure along a plane indicated by the cross-section A-A′ in FIG. 2, according to various embodiments.

FIG. 3B is a vertical cross-sectional view of a further structure along a plane indicated by the cross-section A-A′ in FIG. 2, according to various embodiments.

FIG. 3C is a vertical cross-sectional view of a further structure along a plane indicated by the cross-section A-A′ in FIG. 2, according to various embodiments.

FIG. 3D is a vertical cross-sectional view of a further structure along a plane indicated by the cross-section A-A′ in FIG. 2, according to various embodiments.

FIG. 3E is a vertical cross-sectional view of a further structure along a plane indicated by the cross-section A-A′ in FIG. 2, according to various embodiments.

FIG. 4A is a three-dimensional perspective view of the structure of FIG. 3C, according to various embodiments.

FIG. 4B is a three-dimensional perspective view of the structure of FIG. 3E, according to various embodiments.

FIG. 5A is a vertical cross-sectional view of a structure formed from the structure of FIGS. 3E and 4B, taken along the X-X′ line shown in FIG. 1F, according to various embodiments.

FIG. 5B is a vertical cross-sectional view of a structure formed from the structure of FIGS. 3E and 4B, taken along the Y1-Y1′ line shown in FIG. 1F, according to various embodiments.

FIG. 5C is a vertical cross-sectional view of a structure formed from the structure of FIGS. 3E and 4B, taken along the Y2-Y2′ line shown in FIG. 1F, according to various embodiments.

FIG. 5D is a vertical cross-sectional view of a structure formed from the structure of FIGS. 3E and 4B, taken along the E-E′ line shown in FIG. 1F, according to various embodiments.

FIG. 6 is a flowchart illustrating operations of a method of forming a semiconductor device, according to various embodiments.

FIG. 7 is a flowchart illustrating operations of a further method of forming a semiconductor device, according to various embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows includes embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous by providing a method of fabricating a semiconductor device in which a dielectric etch-stop layer and an amorphous layer are provided over an underlying semiconductor device structure before a cut metal gate operation is performed. For example, according to some embodiments, the semiconductor device includes a gate-all-around field-effect transistor (GAAFET) structure having a metal gate structure formed over a plurality of channel structures including nanostructures. The cut metal gate operation divides the metal gate into a plurality of metal gate portions connected to respective GAAFET structures. The dielectric etch-stop layer prevents loss of the metal gate structure during a subsequent planarization process, thus improving process yield and device performance.

GAAFETs represent an advanced transistor architecture designed to address the limitations of traditional planar transistors and FinFET devices as feature sizes continue to shrink. GAAFETs use a gate structure that fully surrounds the channel region on all sides, which allows for superior control over the channel compared to previous designs. This design effectively reduces leakage current and enhances electrostatic control, making it advantageous for achieving higher performance and power efficiency at nanoscale dimensions. GAAFETs often include nanostructure (e.g., nanosheet or nanowire) channels, which enable greater scalability and help to minimize short-channel effects, a common issue in highly scaled devices. As semiconductor technology nodes advance, GAAFETs are increasingly considered to be a promising solution to improve transistor performance while maintaining the compactness required for densely integrated circuits.

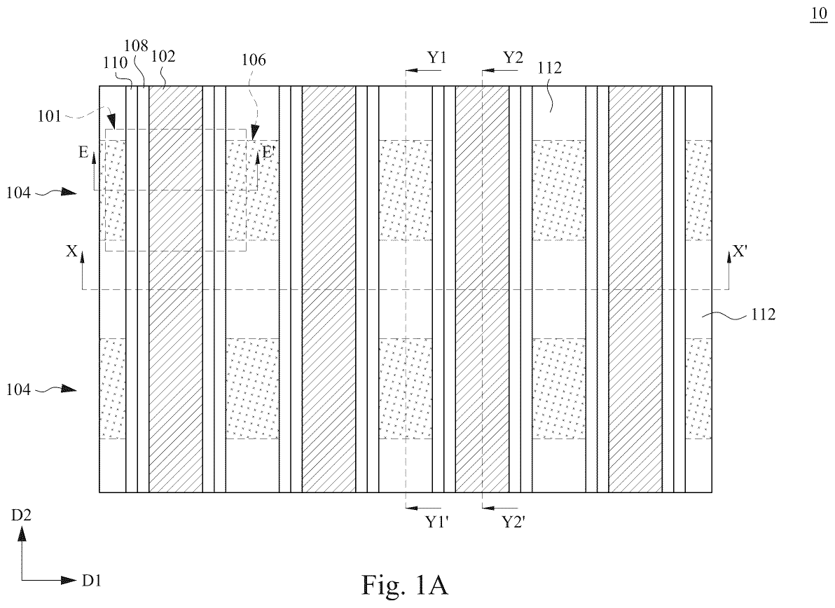

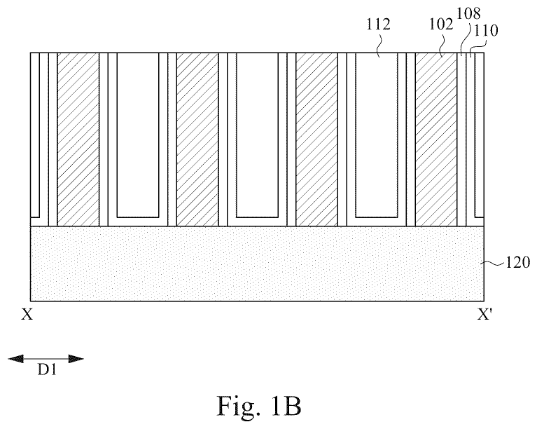

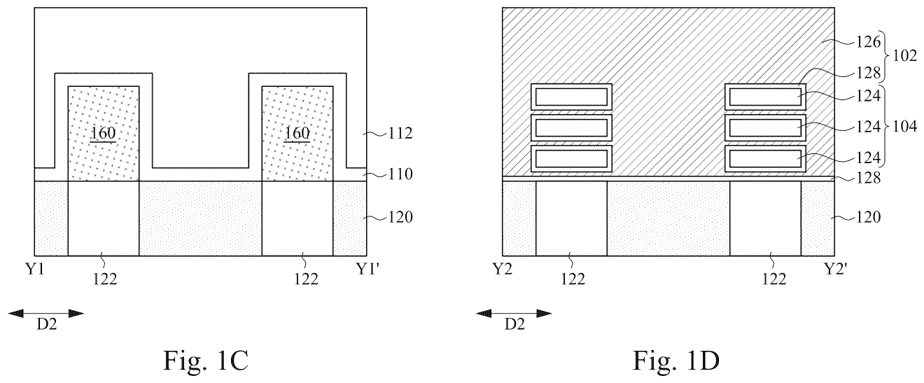

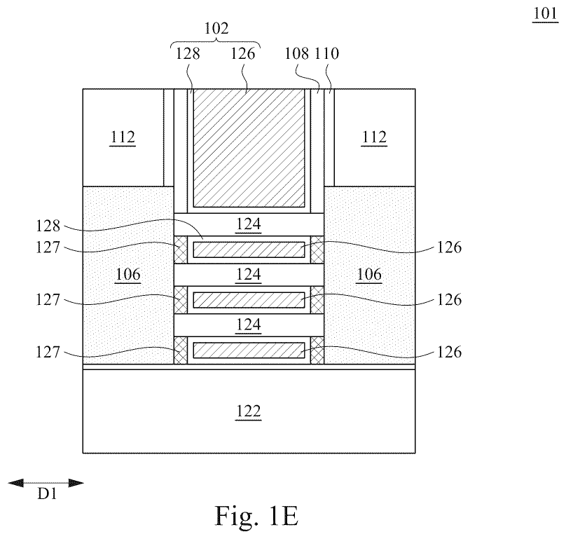

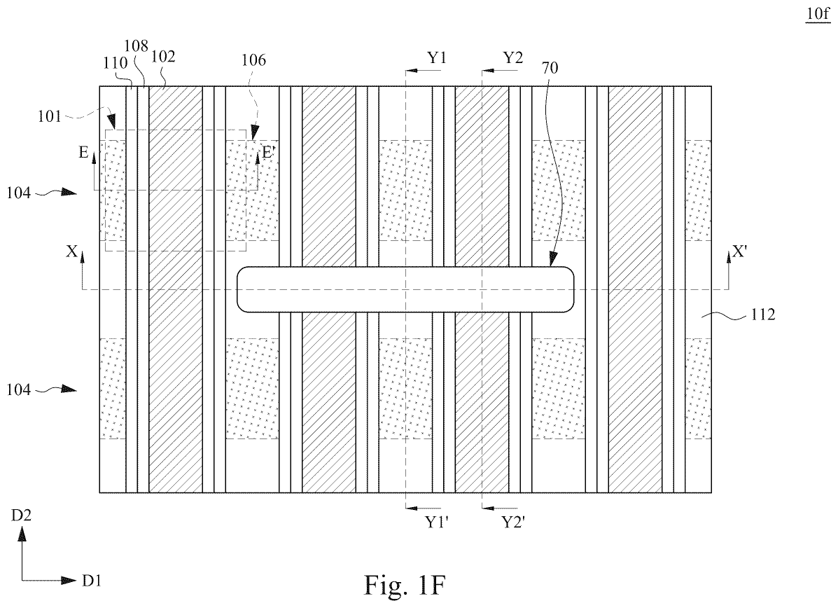

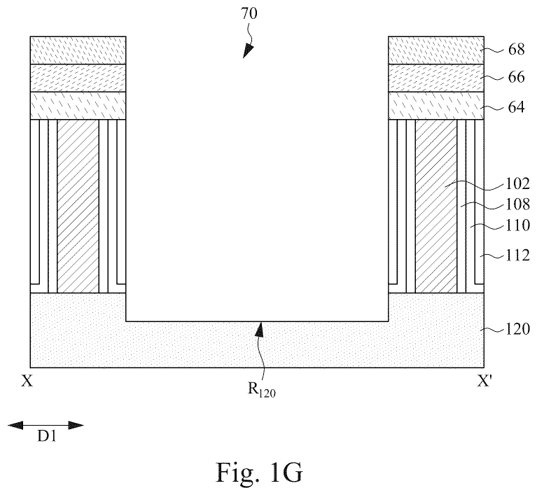

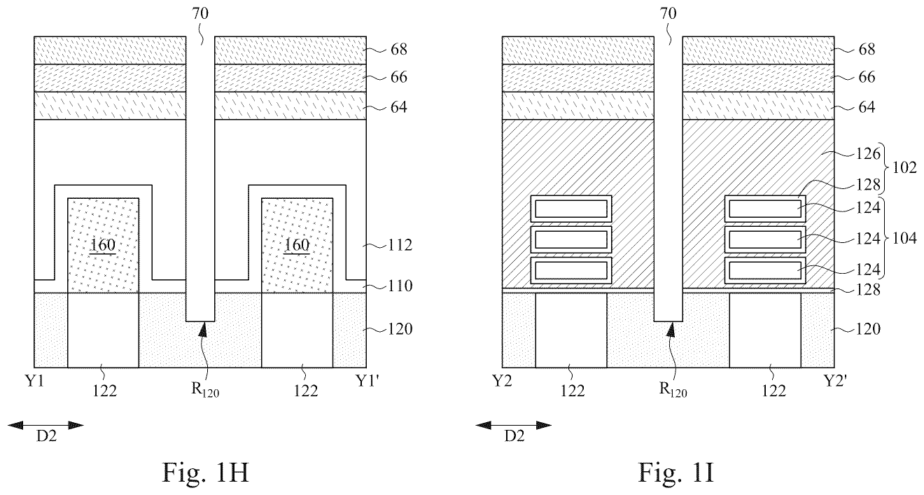

FIG. 1A is a top view of an integrated circuit 10, according to various embodiments. The integrated circuit 10 includes an array of GAAFETs 101, each defined at the intersection of one of multiple gate structures 102 and one of multiple channel structures 104. The channel structures 104 laterally penetrate through the gate structures 102, and source/drain structures 106 of the GAAFETs 101 are disposed in breaks within the channel structures 104 on opposite sides of each gate structure 102. As such, the channel structures 104 are in lateral contact with the source/drain structures 106. Because channel structures 104 are embedded within the gate structures 102 and have breaks at the source/drain structures 106, the channel structures 104 do not appear in the top view of FIG. 1A. Thus, FIG. 1A represents the channel structures 104 by arrows, showing the direction in which the channel structures 104 extend. In some embodiments, the channel structures 104 extend along a first lateral direction D1, while the gate structures 102 extend along a second lateral direction D2, which intersects the first lateral direction D1.

To separate the gate structures 102 from the source/drain structures 106, each gate structure 102 has sidewall spacers 108 lining its opposite sidewalls. Additionally, an etch-stop layer 110 covers the sidewall spacers 108, allowing the sidewall spacers 108 to extend between the gate structures 102 and the etch-stop layer 110. Although not illustrated, the etch-stop layer 110 also covers the source/drain structures 106 and an isolation region 120 surrounding the channel structures 104, which is described with reference to FIGS. 1B through 1D, below. To provide a planar surface for an interconnection structure (not shown) formed over the GAAFETs 101, an interlayer dielectric 112 fills space around the gate structures 102 and is formed to a height substantially level with the top surfaces of the gate structures 102.

FIG. 1B is a vertical cross-sectional view taken along the X-X′ line shown in FIG. 1A; FIG. 1C is a vertical cross-sectional view taken along the Y1-Y1′ line shown in FIG. 1A; FIG. 1D is a vertical cross-sectional view taken along the Y2-Y2′ line shown in FIG. 1A; and FIG. 1E is a vertical cross-sectional view taken along the E-E′ line shown in FIG. 1A, according to various embodiments. As shown in FIG. 1B, FIG. 1C, and FIG. 1D, the isolation region 120 laterally surrounds portions of the semiconductor substrate 122 on which the channel structures 104 and the source/drain structures 106 are formed. As shown in FIG. 1D, the channel structures 104 each include stacks of semiconductor nanostructures 124. Each stack is formed on a portion of the semiconductor substrate 122 and is intersected by one of the gate structures 102. The semiconductor nanostructures 124 in each stack are vertically separated from one another and are wrapped around by the intersecting gate structure 102.

The gate structures 102 each include a gate electrode 126 that wraps around the intersecting semiconductor nanostructures 124 and dielectric layers 128 that separate the gate electrode 126 from the intersecting semiconductor nanostructures 124 and the underlying semiconductor substrate 122. Although not shown, in some embodiments, one or more work function layers extend between each dielectric layer 128 and the gate electrode 126. Additionally, in some embodiments, an interfacial layer (also not shown) lies between each semiconductor nanostructure 124 and the dielectric layer 128.

According to various embodiments, a plurality of operations is performed to form the channel structures 104, the gate structures 102, the sidewall spacers 108, and the source/drain structures 106 of the GAAFETs 101. Before the formation of the channel structures 104, the isolation region 120 is formed in the semiconductor substrate 122. Furthermore, the etch-stop layer 110 is formed along with the gate structures 102. As shown in FIG. 1C, at this stage, the isolation region 120 and the source/drain structures 106 between the gate structures 102 are entirely covered by the etch-stop layer 110. Moreover, after the formation of the GAAFETs 101, the interlayer dielectric layer 112 is introduced between the gate structures 102 to fill the space. As a result, the etch-stop layer 110 is covered by the interlayer dielectric 112.

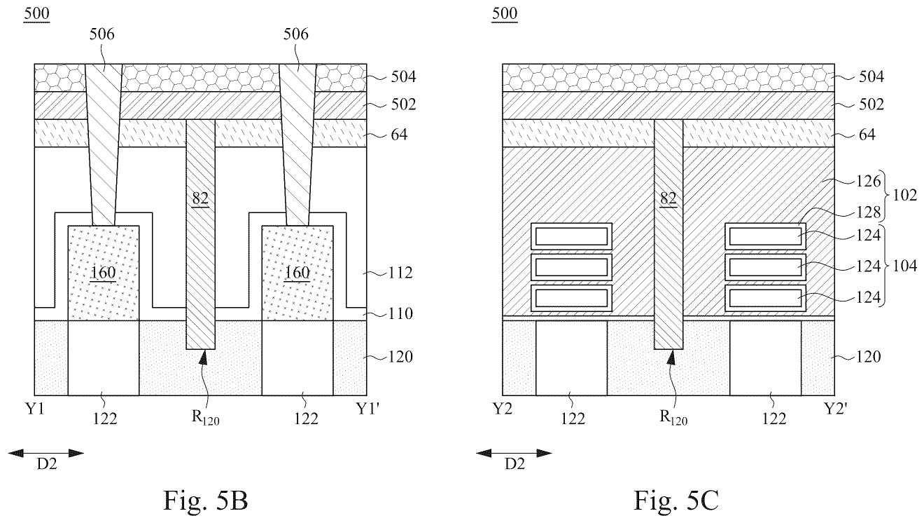

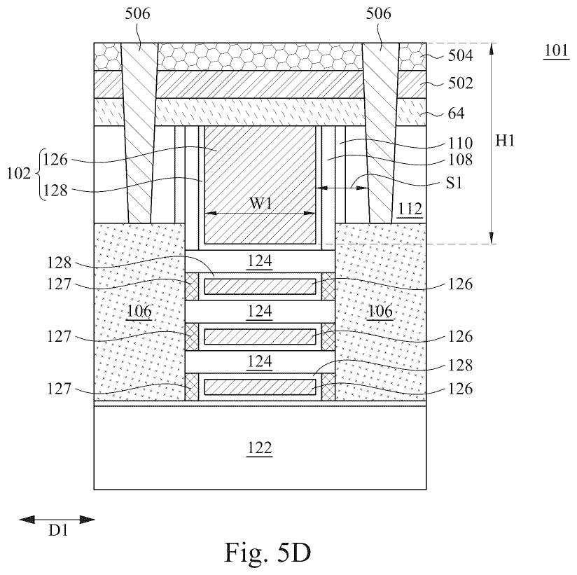

FIG. 1E is a vertical cross-sectional view taken along the E-E′ line shown in FIG. 1A, according to various embodiments. FIG. 1E illustrates one of the GAAFETs 101 described above with reference to FIG. 1A. As shown, the GAAFET 101 includes the stacked semiconductor nanostructures 124 that are configured as channel regions. The gate structure 102 includes gate electrodes 126 that wrap around each of the semiconductor nanostructures 124. Each gate electrode 126 is separated from a respective semiconductor nanostructure 124 by the gate dielectric layers 128. The semiconductor nanostructures 124 are connected to the source/drain structures 106 on opposite ends of the semiconductor nanostructures 124. The source/drain structures 106 are configured to be electrically connected to source/drain contacts 506 in subsequent processing operations (e.g., see FIGS. 5B and 5D). The GAAFET 101 further includes dielectric spacers 127 separating the gate electrodes 126 from the source/drain structures 106

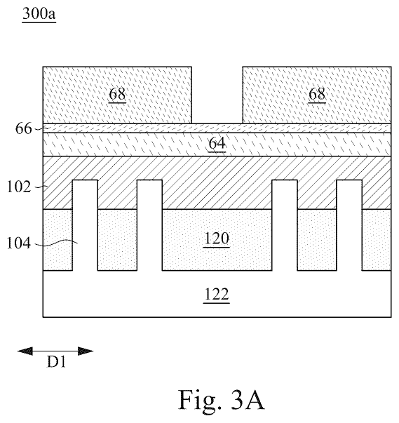

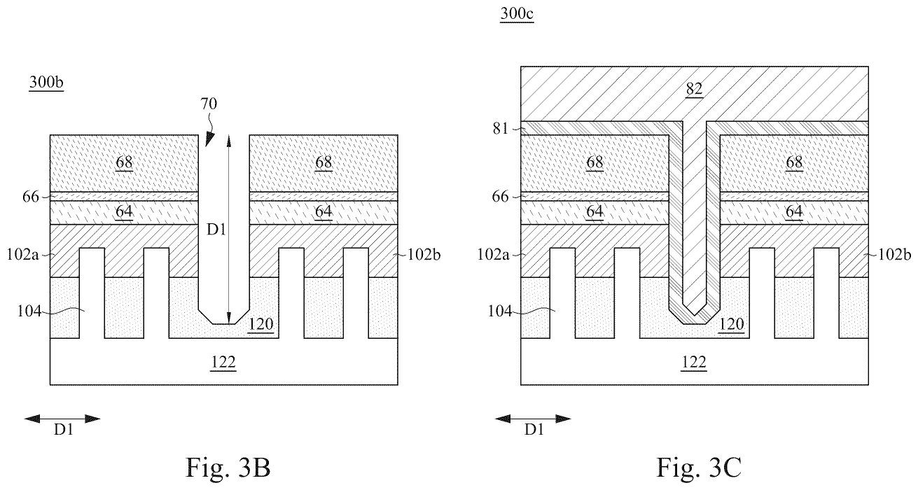

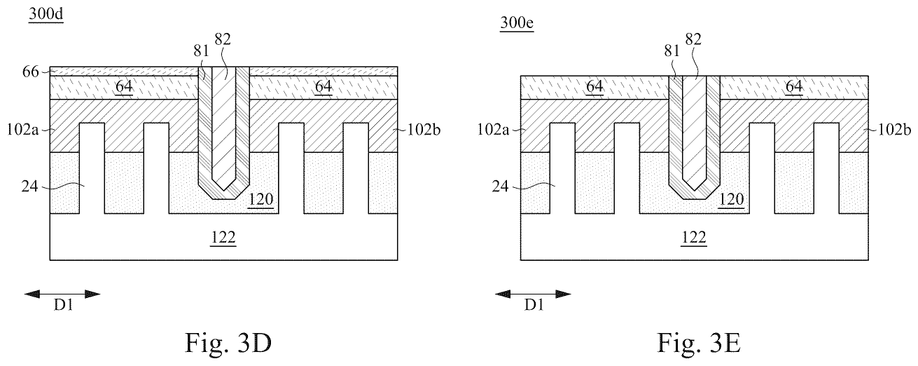

FIG. 1F is a top view of a structure 10f in which an opening 70 has been formed in the integrated circuit 10 of FIGS. 1A to 1E; FIG. 1G is a vertical cross-sectional view taken along the X-X′ line shown in FIG. 1F; FIG. 1H is a vertical cross-sectional view taken along the Y1-Y1′ line shown in FIG. 1F; and FIG. 1I is a vertical cross-sectional view taken along the Y2-Y2′ line shown in FIG. 1F according to various embodiments. As described in greater detail with reference to FIGS. 3A to 3E, below, the opening 70 is formed by an anisotropic etch process after the formation of a dielectric etch stop layer 64, an amorphous layer 66 over the dielectric etch stop layer 64, and a patterned hard mask 68 over the amorphous layer 66. The patterned hard mask 68 is then used as an etch mask during the etch process that forms the opening 70 by etching through the structure including etching the amorphous layer 66 and the dielectric etch stop layer 64. In certain embodiments, a bottom anti-reflective coating (BARC, not shown) is also formed between the amorphous layer 66 and the patterned hard mask 68. The patterned hard mask 68 includes silicon nitride, SiON, SiCN, SiOCN, or the like, and has a thickness between about 50 nm and about 70 nm.

According to some embodiments, the dielectric etch-stop layer 64 is formed of a dielectric material including two or more of silicon, carbon, oxygen, and nitrogen. For example, in some embodiments, the dielectric etch-stop layer 64 includes one or more of SiCO, SiCON, and silicon nitride (SiₓN_{y}), and has a thickness between 1 nm and 3 nm. The presence of the etch-stop layer 64 is to prevent oxidation of the gate structures 102 in subsequent processing operations that are used to form additional dielectric layers (502, 504; see FIGS. 5A to 5D) over the gate structures 102. According to various embodiments, a low-k dielectric material is used for the etch-stop layer 64, such as silicon nitride alloys.

Silicon nitride-based alloys in the form of SiₓN_{y}, where x and y specify the relative compositions of silicon and nitrogen atoms in the material, are used for the dielectric etch-stop layer 64 in various embodiments. These alloys can be tailored by varying x and y to achieve specific properties, such as a lower dielectric constant, enhanced mechanical strength, or improved thermal stability. For example, sub-stoichiometric silicon nitride, where the ratio of silicon to nitrogen is altered (e.g., x>y/3 in SiₓN_{y} compared to stoichiometric Si₃N₄), exhibits a reduced dielectric constant due to the introduction of silicon-rich or nitrogen-deficient structures. Such adjustments can decrease the material's density and polarizability, contributing to a lower k-value while maintaining desirable properties such as diffusion resistance and robustness under thermal cycling. Further modifications, such as doping the SiₓN_{y} matrix with elements like carbon or hydrogen, leads to alloys such as silicon carbon nitride (SiₓCₓN_{y}) or hydrogenated silicon nitride (SiₓN_{y}:H). These variations allow for fine-tuning of the material's electrical and mechanical properties.

According to various embodiments, other low-k dielectrics that are combinations of Si, C, O, and N are used. For example, organosilicate glass (OSG) incorporates carbon into a silicon-oxygen framework, reducing polarizability and achieving dielectric constants between 2.4 and 3.0. Hydrogenated silicon oxycarbide (SiOC:H), also known as carbon-doped silicon dioxide, introduces hydrogen and carbon into a silicon-oxygen matrix to lower the dielectric constant to 2.5-3.0 while enhancing film stability. Silicon carbonitride (SiCN) can be optimized for low-k applications by adjusting the proportions of carbon and nitrogen, achieving k-values as low as 3.0 with improved thermal stability. Porous silicon oxycarbide (p-SiOC) reduces the dielectric constant to below 2.0 by introducing controlled porosity, which decreases density and polarizability, though at the expense of mechanical strength and moisture resistance. Silicon oxycarbonitride (SiOCN) combines silicon, carbon, oxygen, and nitrogen in a hybrid matrix, achieving dielectric constants as low as 2.7 with enhanced thermal and mechanical robustness. Additionally, spin-on silicon oxycarbide (SOD-SiOC), applied as a liquid precursor and cured, provides low-k properties with dielectric constants between 2.5 and 3.0, making it advantageous for filling high-aspect-ratio features. These materials demonstrate the versatility of Si—C—O—N systems in creating low-k dielectrics for use as the etch-stop layer 64.

According to various embodiments, the amorphous layer 66 includes amorphous silicon having a thickness between 3 nm and 7 nm. The amorphous layer 66 is configured to have a material distinction from the patterned hard mask 68 to improve selectivity between the amorphous layer 66 and the patterned hard mask 68. Various other amorphous materials are used in other embodiments, including SiON, amorphous carbon (a-C), amorphous alumina (Al₂O₃), hafnium oxide (HfO₂), titanium nitride alloys (TiₓN_{y}), and tantalum oxide (Ta₂O₅).

The dielectric etch-stop layer 64, the amorphous layer 66, and the patterned hard mask layer 68 are formed by atomic layer deposition (ALD), plasma enhanced chemical vapor deposition (PECVD), or the like. The patterned hard mask 68 is coated over the amorphous layer 66, and the opening 70 is formed in patterned hard mask 68. The opening 70 is formed by forming a patterned photoresist (not shown) over a layer of the hard mask material. The patterned photoresist is then used as an etch mask during an anisotropic etch process that is performed to form the opening 70 in the patterned hard mask 68.

As shown in FIG. 1F, the opening 70 has a lengthwise direction (viewed from the top) perpendicular to the lengthwise direction of the gate structures 102, and portions of gate structures 102 that are cut by the opening 70, as illustrated in FIGS. 1G, 1H, and 1I. As shown in FIGS. 1G to 1I, the opening 70 is formed in the integrated circuit 10 and is positioned between adjacent channel structures 104 and continuously extends across adjacent gate structures 102, dividing each of these gate structures 102 into separate sections. Along with the segmentation of these gate structures 102, the sidewall spacers 108 and portions of the etch-stop layer 110 lining these gate structures 102 are also cut by the opening 70. Additionally, the opposite ends of the opening 70, located at opposite sides of the segmented gate structures 102, are respectively surrounded by portions of the interlayer dielectric 112. A section of the opening 70 that extends between the segmented gate structures 102 cuts through a portion of the interlayer dielectric 112 that fills the space between the segmented gate structures 102.

As shown in FIG. 1G and FIG. 1H, the opening 70 penetrates through the interlayer dielectric 112 and the etch-stop layer 110. As indicated by FIG. 1I, the gate structures 102 intersected by the opening 70 are segmented by the opening 70. In addition, as shown in FIG. 1G, FIG. 1H, and FIG. 1I, the opening 70 further extends into the isolation region 120. As a result, the isolation region 120 is partially recessed to form the recess R120.

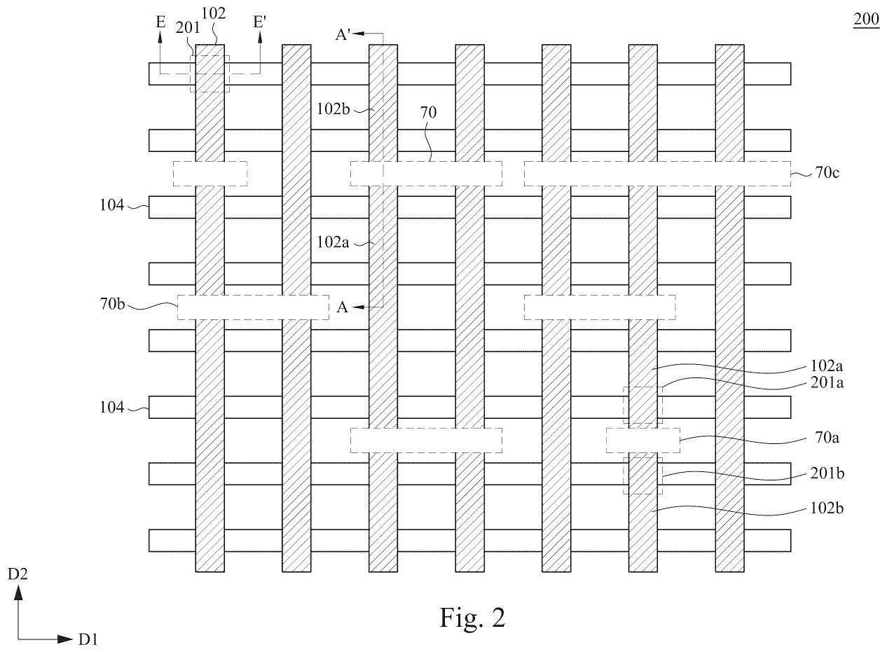

FIG. 2 illustrates a top-down view of an integrated circuit 200, according to various embodiments. As shown in FIG. 2, the integrated circuit 200 is formed as an array of intersecting gate structures 102 and channel structures 104. The channel structures 104 extend parallel to a first direction D1 and are separated from one another along a second direction D2. The gate structures 102 extend along the second direction D2 and are separated from one another along the first direction D1. A plurality of transistors 201 is formed at intersections of respective gate structures 102 and channel structures 104. According to various embodiments, the plurality of transistors 201 are configured as GAAFETs 101, as described above with reference to FIGS. 1A to 1I. Alternatively, in other embodiments, the plurality of transistors 201 are configured as fin field-effect transistors (FinFETs).

As further shown in FIG. 2, the gate structures 102 are divided in various ways by generating openings (70a, 70b, 70c). For example, a first opening 70a has a size that is sufficient to divide a single gate structure 102; a second opening 70b is larger and is sufficient to divide two gate structures 102; and a third opening 70c is sufficient to divide three gate structures 102. In other embodiments, gate structures 102 are divided in various ways using openings 70 of various sizes such that any number of gate structures 102 are divided as needed for respective applications. As shown in FIG. 2, a gate structure 102 of the plurality of gate structures 102 is etched to form an opening 70a that separates the gate structure 102 into a first gate structure portion 102a and a second gate structure portion 102b. Further, the first gate structure portion 102a is connected to a first GAAFET 201a and the second gate structure portion 102b is connected to a second GAAFET 201b.

FIGS. 3A to 3E illustrate a process of dividing the gate structures 102, according to various embodiments. The cross-sectional plane of FIGS. 3A to 3E is indicated by the cross-section A-A′ in FIG. 2. After dividing the gate structures 102, each gate structure 102 will be separated into two separate and electrically isolated gate structures (102a, 102b), each one including a portion of the starting gate structure 102. According to various embodiments, the gate structure 102 is separated into multiple portions of the gate structure 102 by additional simultaneous dividing processes. As shown in FIG. 3B, the amorphous layer 66, the dielectric etch-stop layer 64, the underlying hard mask 110 (see FIGS. 1G and 1H), and the gate electrode 102 are etched to form the opening 70.

Exposed portions of the gate sidewall spacers 108 and the exposed portions of the first ILD layer 112 are also etched (see FIGS. 1G and 1H). The etching process is allowed to continue until the now-exposed gate dielectric layer 128 (e.g., see FIG. 1D) is removed, thereby exposing a portion of the isolation regions 120, as shown in FIG. 3B. In some embodiments, the etching is further continued until at least a portion of the now exposed isolation region 120 is removed (e.g., see FIGS. 1G, 1H, and 1I). In some embodiments, the etching is continued until the isolation regions 120 are removed and a portion of the semiconductor substrate 122 is exposed (not shown in this embodiment). In some embodiments, the etching is continued until a portion of the semiconductor substrate 122 is removed (not shown in this embodiment). In certain embodiments, the etching includes multiple cycles using various etchants effective for the removal of the different materials in the gate structure 102. In some embodiments, the bottom of the opening 70 is disposed in the isolation region 120 and does not penetrate the semiconductor substrate 122, as shown in FIG. 3B.

According to some embodiments, the etching is performed using process gases selected from, and not limited to, Cl₂, BCl₃, Ar, CH₄, CF₄, and combinations thereof. The etching of the gate electrode 102 is performed with a pressure between about 2.5 mTorr and about 25 mTorr. An RF power is applied during etching, and the RF power is between about 250 Watts and about 2,500 Watts. A bias voltage between about 25 volts and about 750 volts is also applied in various embodiments.

In some embodiments, the opening 70 has a depth D1 that coincides with the upper surface of the semiconductor substrate 122 (and does not extend into the substrate). In other embodiments, the depth D1 terminates in an intermediate depth of the isolation region 120, that is, between the upper surface of the isolation region 120 and the lower surface of the isolation region 120, as shown in FIG. 3B. In yet other embodiments, the depth D1 terminates at the top surface of the isolation regions 120 or at the gate dielectric layer 128.

FIG. 3C illustrates the formation of a liner layer 81 within the opening 70 and the deposition of an insulating material over the liner layer 81 to form a gate isolation region 82, according to various embodiments. The liner layer 81 and the gate isolation region 82 are deposited using ALD, PECVD, CVD, spin-on coating, and the like. The filling material includes silicon nitride, silicon oxide, silicon carbide, silicon oxynitride, silicon oxy-carbide, and the like. In some embodiments, the filling material includes other oxides, boron phosphosilicate glass (BPSG), undoped silica glass (USG), fluorosilicate glass (FSG), low-k dielectrics (e.g., having k values lower than 3.9) such as carbon doped oxides, extremely low-k dielectrics such as porous carbon doped silicon dioxide, a polymer such as polyimide, the like, or a combination thereof.

FIGS. 3D and 3E are vertical cross-sectional views of respective structures (300d, 300e) generated by performing planarization operations to remove various layers of the structure 300c of FIG. 3C, according to various embodiments. In this regard, a first planarization operation is performed on the structure 300c of FIG. 3C to generate the structure 300d of FIG. 3D. According various embodiments, a chemical mechanical planarization (CMP) or other planarization operation is performed on the structure 300c to remove the insulating material 82 and the patterned mask structure 68. The first planarization operation is stopped before completely removing the amorphous layer 66. In this regard, the first planarization operation is stopped either when the amorphous layer 66 is reached or after a portion of the amorphous layer 66 is removed. A second planarization operation is then performed to remove the amorphous layer 66. The second planarization operation is stopped when the dielectric etch-stop layer 64 is reached or after a portion of the dielectric etch-stop layer 64 is removed. The difference between these two operations comes from adjusting the selectivity of the slurry.

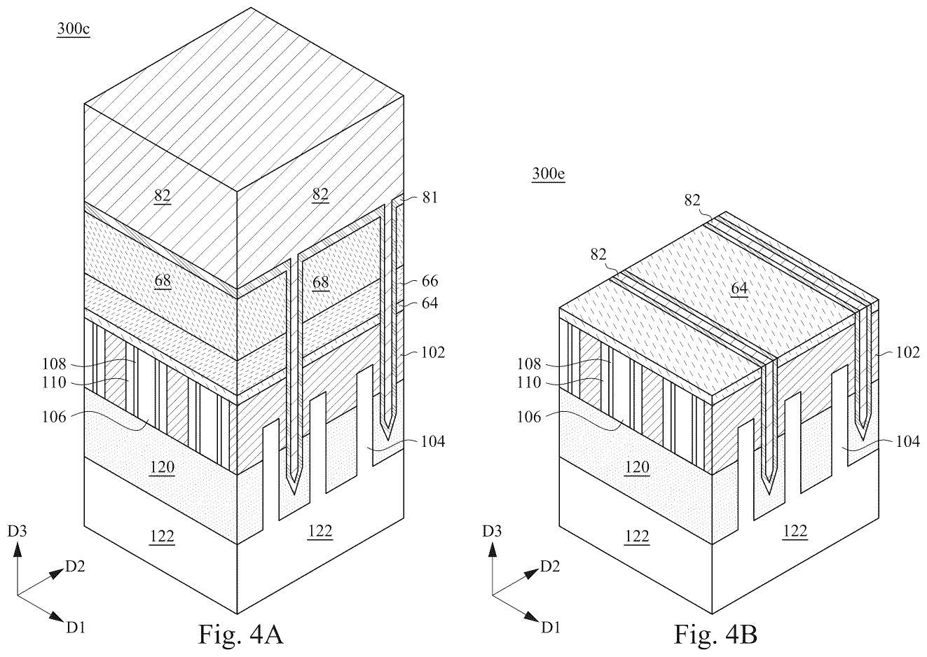

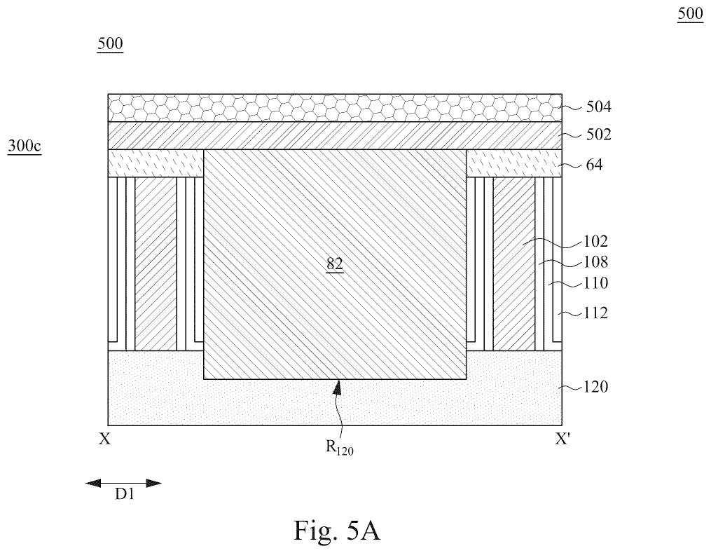

The first planarization is performed to remove the excess portions of the dielectric material of the isolation structure 82, horizontal top portions of the liner layer 81, the patterned hard mask 68, and stopping before removing the amorphous layer 66. As shown, in FIG. 4B, the second planarization process is performed to remove material above a top surface of the dielectric etch-stop layer 64. In certain embodiments, a portion of the dielectric etch-stop layer 64 is also removed but the planarization process is stopped before the entire dielectric etch-stop layer 64 is removed. As such, the dielectric etch-stop layer 64 is advantageous in that it prevents removal of any of the gate structure 102.

FIG. 4A is a three-dimensional perspective view of the structure 300c of FIG. 3C, and FIG. 4B is a three-dimensional perspective view of the structure 300e of FIG. 3E, according to various embodiments. In this regard, as described above, the structure 300e of FIGS. 3E and 4B is formed by performing the first planarization operation on the structure 300c (FIGS. 3C and 4A) to generate the structure 300d of FIG. 3D, followed by performing the second planarization operation on structure 300d.

FIGS. 5A to 5D are vertical cross-sectional views of a structure 500 formed from the structure 300e of FIGS. 3E and 4B, according to various embodiments. FIG. 5A is a vertical cross-sectional view taken along the X-X′ line shown in FIG. 1A; FIG. 5B is a vertical cross-sectional view taken along the Y1-Y1′ line shown in FIG. 1A; FIG. 5C is a vertical cross-sectional view taken along the Y2-Y2′ line shown in FIG. 1A; and FIG. 5D is a vertical cross-sectional view taken along the E-E′ line shown in FIG. 1A, according to various embodiments. The structure 500 is formed by deposition of additional dielectric layers (502, 504) over the structure 300e of FIGS. 3E and 4B followed by formation of source/drain contacts 506, as shown in FIGS. 5B and 5D.

As shown in FIG. 5A, the opening 70 of FIGS. 1F and 1G is filled by the insulating material 82 and is further covered by the additional dielectric layers (502, 504). Similarly, FIGS. 5B and 5B show views corresponding to FIGS. 1H and 1I, respectively, in which the opening 70 is filled by insulating material 82 and is further covered by the additional dielectric layers (502, 504). In the view of FIG. 5B, source/drain contacts 506 are formed and pass through the dielectric layers (64, 502, 504). Lastly, FIG. 5D shows a view of the GAAFET 101 of FIG. 1E after the formation of the additional dielectric layers (502, 504) and source/drain contacts 506. Various dielectric materials are used for the additional dielectric layers (502, 504) including silicon nitride, silicon oxide, SiCO, SiCON, etc. In other embodiments, one or both of the additional dielectric layers (502, 504) include an ILD material such as PSG, BSG, BPSG, USG, or the like. The additional dielectric layers (502, 504) are deposited by any suitable method, such as CVD and PECVD.

As shown in FIGS. 5B and 5D, source/drain contacts 506 are formed as conductive vias that are formed through the dielectric layers (62, 502, 504), the ILD 112, and the lower etch-stop layer 110. As shown in FIGS. 5B, 5C, and 5D, for example, the presence of the dielectric etch-stop layer 64 allows the source/drain contacts 506 to extend to a greater height than the electrode 126. According to various embodiments, the gate electrode 102 has a width W1 that is between about 9 nm and about 12.5 nm. The gate electrode 102 and the second source/drain contacts 506 are spaced apart from one another by a separation S1 is that between about 7 nm and about 9.5 nm and a height difference H1 between about 1 nm and about 4 nm. According to various embodiments, these dimensional estimates can be determined within an accuracy of ±1.0 nm and in other embodiments to within an accuracy of ±0.5 nm.

According to various embodiments, the source/drain contacts 506 are formed as follows. Openings for the source/drain contacts 506 are formed through the additional dielectric layers (502, 504), through the dielectric etch-stop layer 64, and the interlayer dielectric 112. The openings are formed using acceptable photolithography and etching techniques. A liner (not shown), such as a diffusion barrier layer, an adhesion layer, or the like, and a conductive material are formed in the openings. The liner includes titanium, titanium nitride, tantalum, tantalum nitride, or the like. The conductive material is copper, copper alloy, silver, gold, tungsten, cobalt, aluminum, nickel, or the like. A planarization process, such as a CMP, is then performed to remove excess material from a surface of the top dielectric layer 504. The remaining liner and conductive material form the source/drain contacts 506. An annealing process is then performed to form a silicide (not shown) at the interface between the source/drain structures 106 and the source/drain contacts 506. As such, the resulting source/drain contacts 506 are physically and electrically coupled to the source/drain structures 106. As described above, the gate structure 102 connects various numbers of GAAFETs 101 in other parts of the integrated circuit (10, 200) and is connected to gate contacts (not shown) in other parts of the integrated circuit (10, 200) in some embodiments.

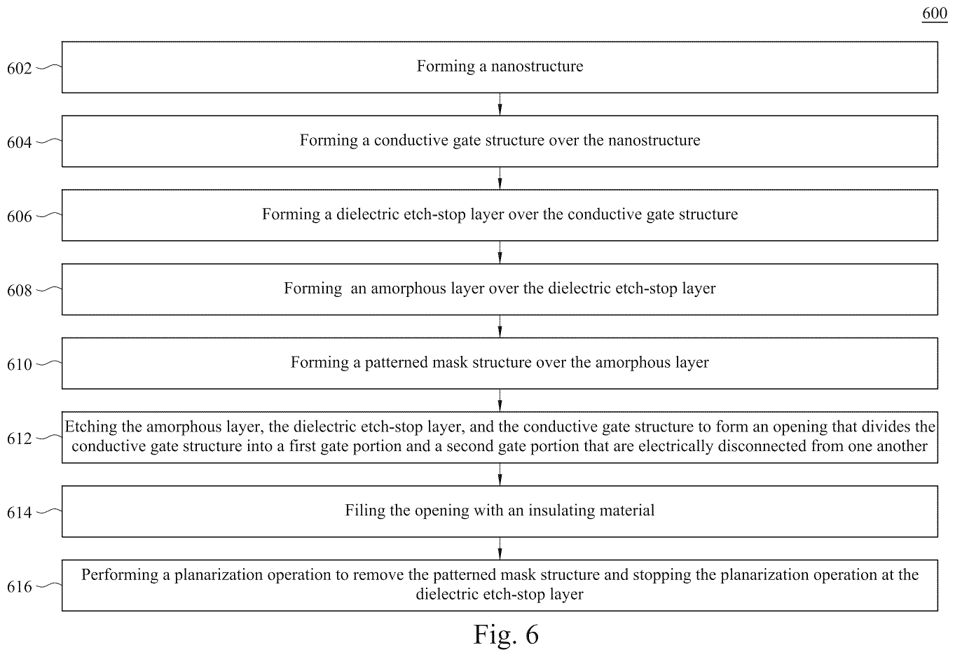

FIG. 6 is a flowchart illustrating operations of a method 600 of forming a semiconductor device (10, 200), according to various embodiments. In operation 602, the method 600 includes forming a nanostructure 124. In operation 604, the method 600 includes forming a conductive gate structure 102 over the nanostructure 124. In operation 606, the method 600 includes forming a dielectric etch-stop layer 64 over the conductive gate structure 102. In operation 608, the method 600 includes forming an amorphous layer 66 over the dielectric etch-stop layer 64. In operation 610, the method 600 includes forming a patterned mask structure 68 over the amorphous layer 66. In operation 612, the method 600 includes etching the amorphous layer 66, the dielectric etch-stop layer 64, and the conductive gate structure 102 to form an opening 70 that divides the conductive gate structure 102 into a first gate portion 102a and a second gate portion 102b that are electrically disconnected from one another. In operation 614, the method 600 includes filling the opening 70 with an insulating material 82. In operation 616, the method 600 includes performing a planarization operation to remove the patterned mask structure 68 and stopping the planarization operation at the dielectric etch-stop layer 64.

According to various embodiments, the dielectric etch-stop layer 64 includes a thickness between about 1 nm and about 3 nm, and none of the conductive gate structure 102 is removed by the planarization operation. According to various embodiments, the dielectric etch-stop layer 64 includes two or more of silicon, carbon, oxygen, and nitrogen. According to various embodiments, the dielectric etch-stop layer 64 includes one or more of silicon nitride, silicon oxide, SiCO, and SiCON, Si₃N₄, Al₂O₃, TiO₂, Ta₂O₅, HfO₂, ZrO₂, and SiC. According to various embodiments, the patterned mask structure 68 includes a hard mask including one or more of silicon nitride, SiON, SiCN, and SiOCN. According to various embodiments, the hard mask includes a silicon nitride layer having a thickness between about 50 nm and about 70 nm.

According to various embodiments, the amorphous layer 66 includes one or more of silicon, silicon oxide, silicon nitride, SiON, amorphous carbon, amorphous alumina, hafnium oxide, boron phosphosilicate glass, phosphosilicate glass, and tantalum oxide. According to various embodiments, the amorphous layer 66 includes amorphous silicon having a thickness between about 3 nm and about 7 nm. According to various embodiments, the method 600 further includes forming a liner layer 81 within the opening 70 and depositing the insulating material 82 such that the insulating material 82 is formed over the liner layer 81. According to various embodiments, the liner layer 81 includes a silicon nitride layer having a first thickness between about 2 nm and about 6 nm, and the insulating material 82 includes a silicon oxide layer having a second thickness between about 20 nm and about 80 nm.

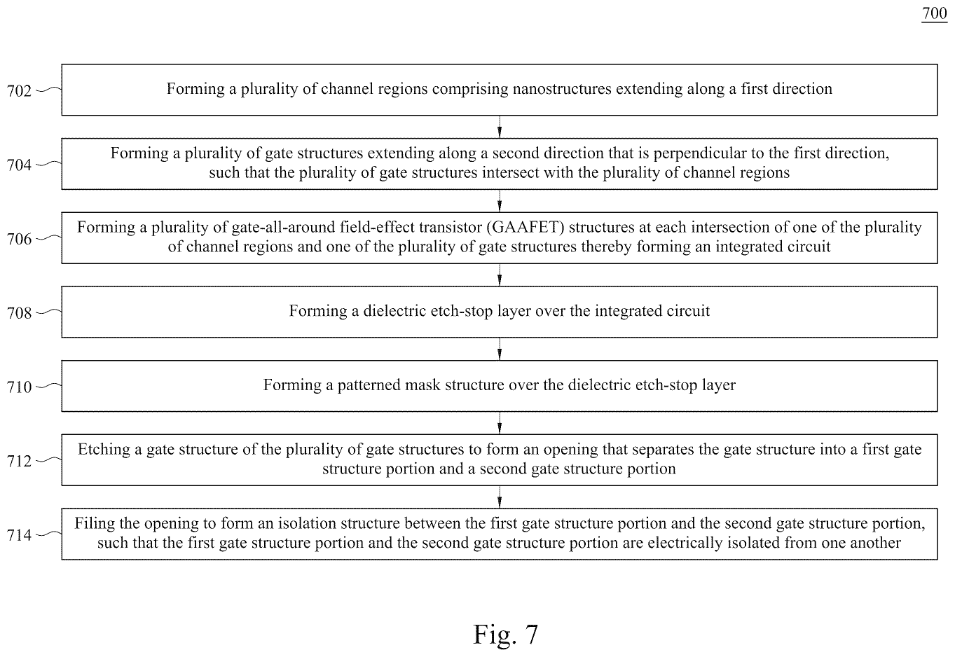

FIG. 7 is a flowchart illustrating operations of a method 700 of forming a semiconductor device (10, 200), according to various embodiments. In operation 702, the method 700 includes forming a plurality of channel structures 104 including nanostructures 124 extending along a first direction D1. In operation 704, the method 700 includes forming a plurality of gate structures 102 extending along a second direction D2 that is perpendicular to the first direction D1, such that the plurality of gate structures 102 intersect with the plurality of channel structures 104. In operation 706, the method 700 includes forming a GAAFET structure 101 at each intersection of one of the plurality of channel structures 104 and one of the plurality of gate structures 102 thereby forming an integrated circuit (10, 200).

In operation 708, the method 700 includes forming a dielectric etch-stop layer 64 over the integrated circuit. In operation 710, the method 700 includes forming a patterned mask structure 68 over the dielectric etch-stop layer 64. In operation 712, the method 700 includes etching a gate structure 102 of the plurality of gate structures 102 to form an opening 70 that separates the gate structure 102 into a first gate portion 102a and a second gate portion 102b. In operation 714, the method 700 includes filling the opening 70 to form an isolation structure 82 between the first gate portion 102a and the second gate portion 102b, such that the first gate portion 102a and the second gate portion 102b are electrically isolated from one another.

According to various embodiments, the method 700 further includes performing a planarization operation to remove the patterned mask structure 68 and a portion of the dielectric etch-stop layer 64. According to various embodiments, the opening 70 extends along the first direction D1 such that the opening 70 is located between adjacent ones of the plurality of channel structures 104. According to various embodiments, in forming the plurality of GAAFET structures 101 according to operation 706, the method 700 further includes forming source/drain structures 106 on opposite sides of each of the plurality of gate structures 102 such that each of the plurality of channel structures 104 is in contact with the source/drain structures 106, such that the first gate portion 102a is connected to a first GAAFET 201a and the second gate portion 102b is connected to a second GAAFET 201b.

According to various embodiments, the dielectric etch-stop layer 64 has a thickness between about 1 nm and about 3 nm, and the dielectric etch-stop layer 64 includes one or more of silicon nitride, silicon oxide, SiCO, and SiCON, Si₃N₄, Al₂O₃, TiO₂, Ta₂O₅, HfO₂, ZrO₂, and SiC. According to various embodiments, the method 600 further includes forming an amorphous layer 66 over the dielectric etch-stop layer 64 before forming the patterned mask structure 68 such that the amorphous layer 66 is formed between the dielectric etch-stop layer 64 and the patterned mask structure 68.

According to various embodiments, the method 600 further includes forming a liner layer 81 including silicon nitride within the opening 70, such that the liner layer 81 includes a first thickness between about 2 nm and about 6 nm, and depositing an insulating material 82 including silicon oxide such that the insulating material 82 is formed over the liner layer 81, fills the opening 70, and includes a second thickness between about 20 nm and about 80 nm.

Referring to all drawings and according to various embodiments of the present disclosure, a semiconductor device (10, 200) is provided. The semiconductor device (10, 200) includes a dielectric etch-stop layer 64 over an integrated circuit structure (10, 200) including a first GAAFET structure 201a, a second GAAFET structure 201b, and a gate structure 102.

The semiconductor device (10, 200) further includes an isolation structure 82 formed in the integrated circuit structure (10, 200) such that the gate structure 102 is divided into a first gate portion 102a and a second gate portion 102b. According to various embodiments, the isolation structure 82 includes an insulating material filling an opening 70 between the first gate portion 102a and the second gate portion 102b, such that the first gate portion 102a and the second gate portion 102b are electrically isolated from one another. According to various embodiments, the first GAAFET structure 201a is connected to the first gate portion 102a and the second GAAFET structure 201b is connected to the second gate portion 102b. According to various embodiments, the dielectric etch-stop layer 64 includes one or more of silicon nitride, silicon oxide, SiCO, and SiCON, Si₃N₄, Al₂O₃, TiO₂, Ta₂O₅, HfO₂, ZrO₂, and SiC and a thickness between about 1 nm and about 3 nm.

Disclosed embodiments are advantageous by providing a method of fabricating a semiconductor device (10, 200) in which a dielectric etch-stop layer 64 and an amorphous layer 66 are provided over an underlying semiconductor device structure (10, 200) before a cut metal gate operation is performed. For example, according to some embodiments, the semiconductor device is a GAAFET structure 101 having a metal gate structure 102 formed over a plurality of channel structures 104 including nanostructures 124. The cut metal gate operation divides the metal gate 102 into a plurality of metal gate portions (102a, 102b) connected to respective GAAFET structures (201a, 201b). The dielectric etch-stop layer 64 prevents loss of the metal gate structure 102 during a subsequent planarization process, thus improving process yield and device performance.

According to various embodiments, a method of forming a semiconductor device includes forming a nanostructure, forming a conductive gate structure over the nanostructure, forming a dielectric etch-stop layer over the conductive gate structure, forming an amorphous layer over the dielectric etch-stop layer, and forming a patterned mask structure over the amorphous layer. According to various embodiments, the method further includes etching the amorphous layer, the dielectric etch-stop layer, and the conductive gate structure to form an opening that divides the conductive gate structure into a first gate portion and a second gate portion that are electrically disconnected from one another, filling the opening with an insulating material, and performing a planarization operation to remove the patterned mask structure and stopping the planarization operation at the dielectric etch-stop layer.

According to various embodiments, the dielectric etch-stop layer includes a thickness between 1 nm and 3 nm and none of the conductive gate structure is removed by the planarization operation. According to various embodiments, the dielectric etch-stop layer includes two or more of silicon, carbon, oxygen, and nitrogen. According to various embodiments, the dielectric etch-stop layer includes one or more of one or more of silicon nitride, silicon carbide, silicon oxycarbide, silicon carbide nitride, SiCON, SiOC:H, SiN:H, porous silicon oxycarbide, organosilicate glass, and alloys of silicon, carbon, oxygen, and nitrogen. According to various embodiments, the patterned mask structure includes a hard mask including one or more of silicon nitride, SiON, SiCN, and SiOCN. According to various embodiments, the hard mask includes a silicon nitride layer having a thickness between 50 nm and 70 nm.

According to various embodiments, the amorphous layer includes one or more of amorphous silicon, amorphous carbon, amorphous alumina, silicon oxynitride, hafnium oxide, titanium nitride, tantalum oxide, and alloys thereof. According to various embodiments, the amorphous layer includes amorphous silicon having a thickness between 3 nm and 7 nm. According to various embodiments, the method further includes forming a liner layer within the opening and depositing the insulating material such that the insulating material is formed over the liner layer. According to various embodiments, the liner layer includes a silicon nitride layer having a first thickness between 2 nm and 6 nm and the insulating material includes a silicon oxide layer having a second thickness between 20 nm and 80 nm.

According to various embodiments, a method of forming a semiconductor device includes forming a plurality of channel structures including nanostructures extending along a first direction, forming a plurality of gate structures extending along a second direction that is perpendicular to the first direction, such that the plurality of gate structures intersect with the plurality of channel structures, and forming a plurality of GAAFET structures at each intersection of one of the plurality of channel structures and one of the plurality of gate structures thereby forming an integrated circuit. According to various embodiments, the method further includes forming a dielectric etch-stop layer over the integrated circuit, forming a patterned mask structure over the dielectric etch-stop layer, etching a gate structure of the plurality of gate structures to form an opening that separates the gate structure into a first gate structure portion and a second gate structure portion, and filling the opening to form an isolation structure between the first gate structure portion and the second gate structure portion, such that the first gate structure portion and the second gate structure portion are electrically isolated from one another.

According to various embodiments, the method further includes performing a planarization operation to remove the patterned mask structure and a portion of the dielectric etch-stop layer. According to various embodiments, the opening extends along the first direction such that the opening is located between adjacent ones of the plurality of channel structures. According to various embodiments, forming the plurality of GAAFET structures further includes forming source/drain structures on opposite sides of each of the plurality of gate structures such that each of the plurality of channel structures is in contact with the source/drain structures, such that the first gate structure portion is connected to a first GAAFET and the second gate structure portion is connected to a second GAAFET.

According to various embodiments, the dielectric etch-stop layer includes a thickness between 1 nm and 3 nm, and the dielectric etch-stop layer includes one or more of silicon nitride, silicon oxide, SiCO, and SiCON, Si₃N₄, Al₂O₃, TiO₂, Ta₂O₅, HfO₂, ZrO₂, and SiC. According to various embodiments, the method further includes forming an amorphous layer over the dielectric etch-stop layer before forming the patterned mask structure such that the amorphous layer is formed between the dielectric etch-stop layer and the patterned mask structure. According to various embodiments, the method further includes forming a liner layer including silicon nitride within the opening, such that the liner layer includes a first thickness between 2 nm and 6 nm, and depositing an insulating material including silicon oxide such that the insulating material is formed over the liner layer, fills the opening, and includes a second thickness between 20 nm and 80 nm.

According to various embodiments, a semiconductor device includes a dielectric etch-stop layer formed over an integrated circuit structure including a first GAAFET structure, a second GAAFET structure, and a gate structure; and an isolation structure formed in the dielectric etch-stop layer and the integrated circuit structure such that the gate structure is divided into a first gate structure portion and a second gate structure portion. According to various embodiments, the isolation structure includes an insulating material filling an opening between the first gate structure portion and the second gate structure portion, such that the first gate structure portion and the second gate structure portion are electrically isolated from one another.

According to various embodiments, the first GAAFET structure includes the first gate structure portion and the second GAAFET structure includes the second gate structure portion. According to various embodiments, the dielectric etch-stop layer includes one or more of silicon nitride, silicon oxide, SiCO, and SiCON, Si₃N₄, Al₂O₃, TiO₂, Ta₂O₅, HfO₂, ZrO₂, and SiC and a thickness between 1 nm and 3 nm.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of forming a semiconductor device, comprising:
forming a nanostructure;
forming a conductive gate structure over the nanostructure;
forming a dielectric etch-stop layer over the conductive gate structure;
forming an amorphous layer over the dielectric etch-stop layer;
forming a patterned mask structure over the amorphous layer;
etching the amorphous layer, the dielectric etch-stop layer, and the conductive gate structure to form an opening that divides the conductive gate structure into a first gate portion and a second gate portion that are electrically disconnected from one another;
filling the opening with an insulating material; and
performing a planarization operation to remove the patterned mask structure and stopping the planarization operation at the dielectric etch-stop layer.

2. The method of claim 1, wherein:
the dielectric etch-stop layer comprises a thickness between 1 nm and 3 nm; and
none of the conductive gate structure is removed by the planarization operation.

3. The method of claim 1, wherein the dielectric etch-stop layer comprises two or more of silicon, carbon, oxygen, and nitrogen.

4. The method of claim 3, wherein the dielectric etch-stop layer comprises one or more of silicon nitride, silicon carbide, silicon oxycarbide, silicon carbide nitride, SiCON, SiOC:H, SiN:H, porous silicon oxycarbide, organosilicate glass, and alloys of silicon, carbon, oxygen, and nitrogen.

5. The method of claim 1, wherein the patterned mask structure comprises a hard mask comprising one or more of silicon nitride, SiON, SiCN, and SiOCN.

6. The method of claim 5, wherein the hard mask comprises a silicon nitride layer having a thickness between 50 nm and 70 nm.

7. The method of claim 1, wherein the amorphous layer comprises one or more of amorphous silicon, amorphous carbon, amorphous alumina, silicon oxynitride, hafnium oxide, titanium nitride, tantalum oxide, and alloys thereof.

8. The method of claim 7, wherein the amorphous layer comprises amorphous silicon having a thickness between 3 nm and 7 nm.

9. The method of claim 1, further comprising:
forming a liner layer within the opening; and
depositing the insulating material such that the insulating material is formed over the liner layer.

10. The method of claim 9, wherein:
the liner layer comprises a silicon nitride layer having a first thickness between 2 nm and 6 nm; and
the insulating material comprises a silicon oxide layer having a second thickness between

20. nm and 80 nm.

11. A method of forming a semiconductor device, comprising:
forming a plurality of channel structures comprising nanostructures extending along a first direction;
forming a plurality of gate structures extending along a second direction that is perpendicular to the first direction, such that the plurality of gate structures intersect with the plurality of channel structures;
forming a gate-all-around field-effect transistor (GAAFET) structure at each intersection of one of the plurality of channel structures and one of the plurality of gate structures thereby forming an integrated circuit;
forming a dielectric etch-stop layer over the integrated circuit;
forming a patterned mask structure over the dielectric etch-stop layer;
etching a gate structure of the plurality of gate structures to form an opening that separates the gate structure into a first gate structure portion and a second gate structure portion; and
filling the opening to form an isolation structure between the first gate structure portion and the second gate structure portion, such that the first gate structure portion and the second gate structure portion are electrically isolated from one another.

12. The method of claim 11, further comprising:
performing a planarization operation to remove the patterned mask structure and a portion of the dielectric etch-stop layer.

13. The method of claim 12, wherein the opening extends along the first direction such that the opening is located between adjacent ones of the plurality of channel structures.

14. The method of claim 12, wherein forming the plurality of GAAFET structures further comprises:
forming source/drain structures on opposite sides of each of the plurality of gate structures such that each of the plurality of channel structures is in contact with the source/drain structures,
wherein the first gate structure portion is connected to a first GAAFET and the second gate structure portion is connected to a second GAAFET.

15. The method of claim 12, wherein:
the dielectric etch-stop layer comprises a thickness between 1 nm and 3 nm; and
the dielectric etch-stop layer comprises one or more of silicon nitride, silicon oxide, SiCO, and SiCON, Si₃N₄, Al₂O₃, TiO₂, Ta₂O₅, HfO₂, ZrO₂, and SiC.

16. The method of claim 11, further comprising:
forming an amorphous layer over the dielectric etch-stop layer before forming the patterned mask structure such that the amorphous layer is formed between the dielectric etch-stop layer and the patterned mask structure.

17. The method of claim 11, further comprising:
forming a liner layer comprising silicon nitride within the opening, such that the liner layer comprises a first thickness between 2 nm and 6 nm; and
depositing an insulating material comprising silicon oxide such that the insulating material is formed over the liner layer, fills the opening, and comprises a second thickness between 20 nm and 80 nm.

18. A semiconductor device, comprising:
a dielectric etch-stop layer over an integrated circuit structure comprising a first GAAFET structure, a second GAAFET structure, and a gate structure; and
an isolation structure formed in the integrated circuit structure such that the gate structure is divided into a first gate structure portion and a second gate structure portion,
wherein the isolation structure comprises an insulating material filling an opening between the first gate structure portion and the second gate structure portion, such that the first gate structure portion and the second gate structure portion are electrically isolated from one another.

19. The semiconductor device of claim 18, wherein:
the first GAAFET structure is connected to the first gate structure portion and the second GAAFET structure is connected to the second gate structure portion.

20. The semiconductor device of claim 18, wherein the dielectric etch-stop layer comprises one or more of silicon nitride, silicon oxide, SiCO, and SiCON, Si₃N₄, Al₂O₃, TiO₂, Ta₂O₅, HfO₂, ZrO₂, and SiC and a thickness between 1 nm and 3 nm.
